(19) United States
(12) Patent Application Publication
(10) Pub. No.: US 2024/0379644 A1
(43) Pub. Date: Nov. 14, 2024

(54) Optical Communication Device

(71) Applicant: Nippon Telegraph and Telephone Corporation, Tokyo (JP)

(72) Inventors: Toshihiro Ito, Musashino-shi, Tokyo (JP); Masayuki Takahashi, Musashino-shi, Tokyo (JP)

(21) Appl. No.: 18/691,757

(22) PCT Filed: Sep. 27, 2021
(86) PCT No.: PCT/JP2021/035447

§ 371 Date: Mar. 13, 2024

(51) Int. Cl. H01L 25/16; G02F 1/21; H01L 31/02; H01L 31/0232

(52) U.S. Cl. CPC H01L 25/167; G02F 1/212; H01L 31/02005; H01L 31/02327

(57) ABSTRACT

An optical communication device includes: a semiconductor chip that includes an optical waveguide formed in the semiconductor chip, and G pads, a P pad, and S pads for outputting electrical signals indicating intensity of light propagating in the optical waveguide; and a semiconductor chip that includes G pads and S pads electrically connected to the G pads, the P pad, and the S pads, and is connected to the semiconductor chip, wherein the center points of at least some of the S pads are located on straight lines on at least one of the chips, the straight lines being parallel to sides, and the center points of the other electrode pads are located on other straight lines farther from the sides than the straight lines.

### TECHNICAL FIELD

The present invention relates to an optical communication device.

### BACKGROUND ART

With the development of various applications such as social media and video distribution services, and the installation of data centers, 5G infrastructures, and the like, the Internet in the world continues to expand, and the optical communication capacities responsible for backbones also continues to increase. In this trend, there is a demand for optical communication devices that are capable of large-capacity transmission not only in long-distance communication between local regions and the like but also in middle-distance communication and short-distance communication such as communications in a data center, and are also capable of high-speed optical transmission and reception at low costs.

In short-distance communication, not only optical communication devices of a simple direct intensity modulation scheme but also digital coherent optical communication devices are used more often than before. A digital coherent optical communication device can greatly increase transmission capacity by modulating both the phase and the intensity of light with an optical modulator, and further performing polarization multiplexing. With such a digital coherent optical communication device, it is possible to perform large-capacity communication for transmitting and receiving data of 400 Gbps or more at one wavelength. Such a technology is disclosed in Patent Literature 1, for example.

### CITATION LIST

### Patent Literature

Patent Literature 1: Japanese Patent No. 6740206

### SUMMARY OF INVENTION

FIG. 11 is a diagram illustrating the upper surface of an optical receiver 100 disclosed in Patent Literature 1. As illustrated in FIG. 11, the optical receiver 100 is formed by connecting an optical semiconductor chip 110 and a semiconductor chip 130 to a package substrate 140. The optical semiconductor chip 110 includes a dual-polarization optical hybrid 111 and a dual photodiode 112, and includes anodes S1 and S2 and cathodes CA1 and CA2 as terminals. The semiconductor chip 130 includes a transimpedance amplifier 131, and includes differential input terminals T1 and T2 as terminals. In FIG. 11, electrode pads (hereinafter also referred to simply as “pads”) are denoted by “S1” and the like. Note that the optical receiver 100 has channels C1 to C4 including the photodiode 112 and the transimpedance amplifier 131. In FIG. 11, only the configuration of the channel C1 is illustrated, and those of the channels C2, C3, and C4 are not shown, for ease of explanation.

As illustrated in FIG. 11, the semiconductor chip 110 and the semiconductor chip 130 are disposed side by side on the package substrate 140 so that sides E_{A} and E_{B} are located close to each other. To prevent degradation of a high-frequency signal between the semiconductor chip 110 and the semiconductor chip 130, the anodes S1 and S2, the cathodes CA1 and CA2, and the differential input terminals T1 and T2 are disposed at positions relatively close to the sides E_{A} and E_{B}.

Meanwhile, the semiconductor chips 110 and 130 are inspected with probes before being formed into chips, or in a wafer state. The inspection device includes a plurality of probes so that a large number of pads can be inspected at once. Probes involving a plurality of signals, a ground, and the like for measuring a high-frequency signal are normally designed so that the tips of the probe needles are located on a straight line when the probes come into contact with pads. Such a configuration is often adopted, because such a configuration makes it easier to manufacture a structure in which the signal-ground distances of the probes are kept constant regardless of the positions of the pads, and the impedance of the line is kept at a constant value in each pad.

In view of the above, in the optical receiver 100, the anodes S1 and S2 and the cathodes CA1 and CA2 are disposed on the semiconductor chip 110 so as to pass through a straight line L_{A}, and the differential input terminals T1 and T2 are disposed so as to pass through a straight line L_{B}, as illustrated in FIG. 11. Here, the center points of the pads formed on the anodes S1 and S2 and the cathodes CA1 and CA2 are located on the straight line L_{A}. Also, the center points of the differential input terminals T1 and T2 are located on the straight line L_{B}.

However, in a case where a semiconductor chip is connected to a package substrate by flip-chip bonding, the pads need to have a size of about 100 μm, for example. Also, in the case of a coherent optical receiver, as illustrated in FIG. 11, the single receiver 100 includes the dual photodiode 112 and the transimpedance amplifier 131, which are equivalent to four channels. When the device is made smaller in size, the intervals between the channels C1 and C2, and the others become narrower, and the distances between the pads become shorter. This aspect causes a problem in that parasitic capacitance is easily added to signal lines 121, and to the pads of the anodes S1 and S2 and the differential input terminals T1 and T2. For example, in a case where pads having a size of 100 μm are provided on a chip having a signal-ground pitch (center interval) of 150 μm, the pad intervals are 50 μm. The pads arranged at such intervals have electrostatic capacitance in between. This inter-pad electrostatic capacitance is added to the electrostatic capacitance that the pad has with respect to the substrate, and affects high-frequency characteristics. As the device size becomes smaller and the channel intervals become narrower, the demand for narrower pad intervals increases, and the proportion of the pad capacitance becomes relatively higher.

Further, in a case where connection is performed by flip-chip bonding, the package substrate 140 illustrated in FIG. 11 is connected to the semiconductor chips 110 and 130, with the principal surfaces being made to face each other thereon, and the space between the semiconductor chips 110 and 130 is filled with an underfill material having a relative dielectric constant of 4, for example. For this reason, flip-chip bonding is likely to generate electrostatic capacitance in particular. In a case where the transmission rate is 64 Gbaud or higher, the electrostatic capacitance affects the optical-electrical characteristics in an optical receiver, and the electrical-optical frequency characteristics in an optical transmitter, which might lead to a lower signal quality.

The present disclosure has been made in view of the above aspects, and relates to an optical communication device that is advantageous for miniaturization because the optical communication device hardly generates parasitic capacitance even when channels are disposed close to each other on a semiconductor chip, and is capable of preventing degradation of quality of high-speed signals.

To achieve the above object, an optical communication device of one mode of the present disclosure includes: a first chip including an optical waveguide, and a plurality of first electrode pads for outputting an electrical signal indicating intensity of light propagating in the optical waveguide; and a second chip including a plurality of second electrode pads that are connected directly to the first electrode pads, or are electrically connected to the first electrode pads via another substrate. The first electrode pads and the second electrode pads include a plurality of signal pads that transmit the electrical signal. The center points of at least some signal pads of the plurality of signal pads are located on a straight line on at least one of the first chip and the second chip, the straight line being a line parallel to a side facing the other one of the first chip and the second chip. The center points of the other first electrode pads and the other second electrode pads are located on another straight line farther from the facing side than the straight line.

According to the above mode, it is possible to provide an optical communication device that is advantageous for miniaturization, because the optical communication device hardly generates parasitic capacitance even when channels are disposed close to each other on a semiconductor chip, and is capable of preventing degradation of quality of high-speed signals.

### BRIEF DESCRIPTION OF DRAWINGS

FIG. 1(a) is a top view of an optical communication device according to a first embodiment, and FIG. 1(b) is a schematic cross-sectional view taken along the line between arrows Ib and Ib defined in FIG. 1(a).

FIG. 2(a) is a view of partial regions of semiconductor chips illustrated in FIG. 1(a) as viewed from above. FIG. 2(b) is a view of a partial region of a package substrate as viewed from above.

FIGS. 3(a) and 3(b) are diagrams for explaining the effects of the first embodiment.

FIG. 4 is a top view of an optical communication device according to a second embodiment.

FIG. 5(a) is a view of a partial region of a semiconductor chip of the second embodiment as viewed from above. FIG. 5(b) is a view of a partial region A4 of a package substrate of the second embodiment as viewed from above.

FIG. 6 is a diagram for explaining a state of on-wafer measurement according to the second embodiment.

FIG. 7(a) is a view of a partial region of a semiconductor chip of a third embodiment as viewed from above. FIG. 7(b) is a view of a partial region of a package substrate as viewed from above.

FIG. 8(a) is a view of a partial region of a semiconductor chip of another example of the third embodiment as viewed from above. FIG. 8(b) is a view of a partial region of a package substrate of another example as viewed from above.

FIG. 9(a) is a top view of an optical communication device according to a fourth embodiment, and FIG. 9(b) is a schematic cross-sectional view taken along the line between arrows IXb and IXb defined in FIG. 9(a).

FIGS. 10(a) and 10(b) are views of upper surfaces in a state before two semiconductor chips overlap each other in two cases of a fifth embodiment.

FIG. 11 is a diagram for explaining a known optical receiver.

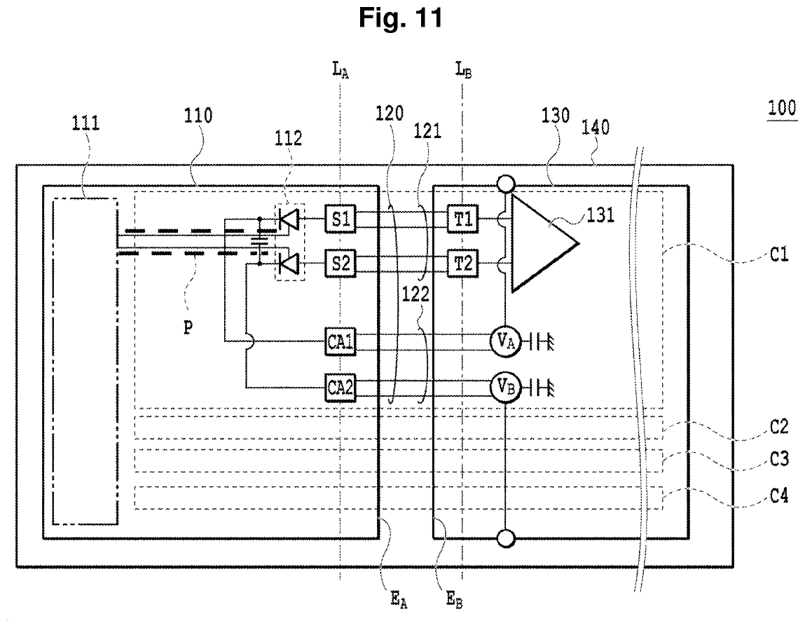

### DESCRIPTION OF EMBODIMENTS

In the description below, first to fifth embodiments of the present invention (the first to fifth embodiments will be hereinafter also collectively referred to as “the present embodiment”) are explained. The drawings to be used in the description of the present embodiment are intended to describe the functions, the configurations, the arrangement of the respective components, and the idea of the present disclosure, and do not limit them to specific shapes and designs. Therefore, at least some of the drawings are schematic diagrams, and the aspect ratios, the thicknesses, and the like of the components are not necessarily accurately expressed in the drawings. Further, the term “optical communication device” described below indicates that the optical communication device has at least one of a function of transmitting optical signals and a function of receiving optical signals.

### First Embodiment

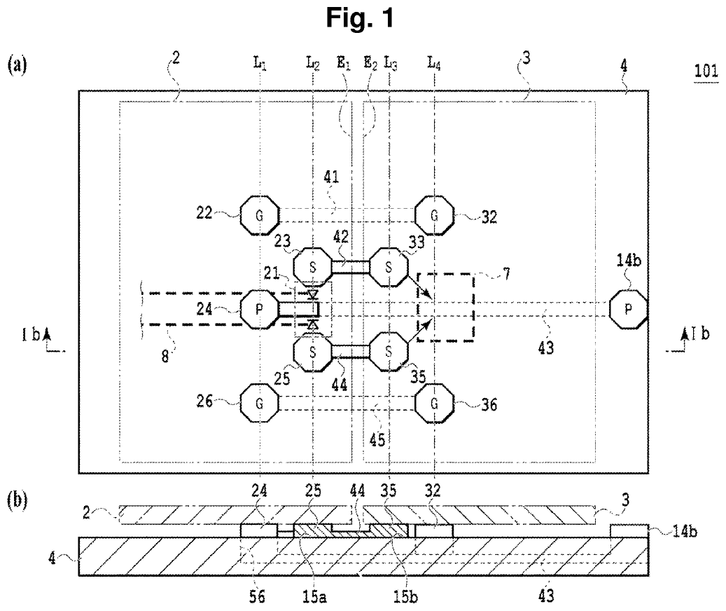

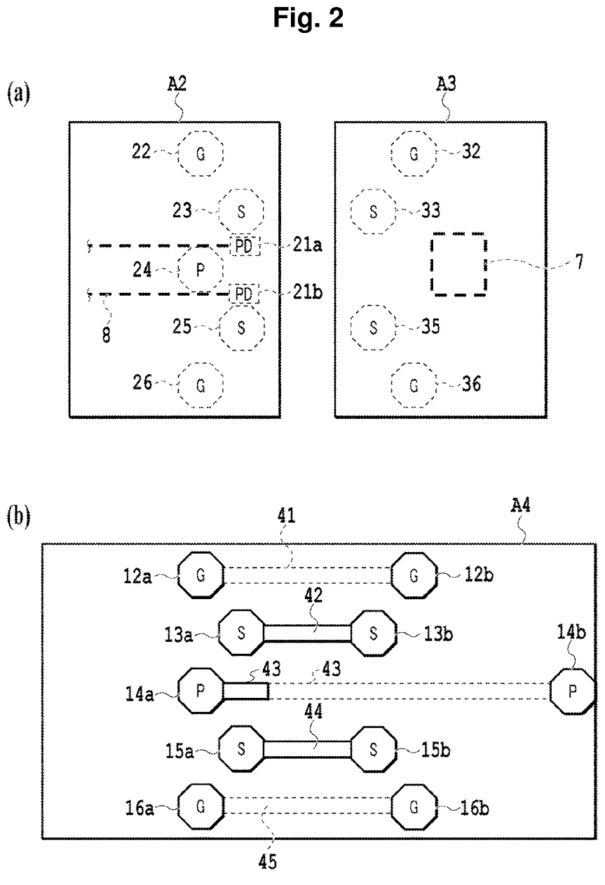

FIGS. 1(a), 1(b), 2(a), and 2(b) are diagrams for explaining an optical communication device 101 according to a first embodiment of the present disclosure. FIG. 1(a) is a top view of the optical communication device 101. FIG. 1(b) is a schematic cross-sectional view taken along the line between arrows Ib and Ib defined in FIG. 1(a), and shows a cross-section and a partial end face. FIG. 2(a) is a view of a partial region A2 of a semiconductor chip 2 and a partial region A3 of a semiconductor chip 3 illustrated in FIG. 1(a) as viewed from above. FIG. 2(b) is a view of a partial region A4 of a package substrate 4 as viewed from above. In the present embodiment, the semiconductor chips 2 and 3 are disposed at higher positions than the package substrate 4, the position of the package substrate 4 being the reference position. Further, for the optical communication device 101, the side of the semiconductor chips 2 and 3 is defined as the upper side, and the side of the package substrate 4 is defined as the lower side.

Also, in the present embodiment, the principal surface of the package substrate 4 facing the semiconductor chips 2 and 3 is defined as the upper surface of the package substrate 4, and the back surface thereof is defined as the lower surface. Also, of the principal surfaces of the semiconductor chips 2 and 3, the principal surfaces facing the package substrate 4 are defined as the lower surfaces, and the back surfaces thereof are defined as the upper surfaces. Such definition of the upper and lower sides/surfaces does not depend on the direction of attachment of the optical communication device 101. Further, a “principal surface” is the surface clearly having a larger area than the other surfaces in each of the semiconductor chips 2 and 3 and the package substrate 4. In FIG. 2(a), G pads and the like formed on the lower surfaces of the semiconductor chips 2 and 3 are indicated by dashed lines. In FIG. 2(b), the portions of lines formed inside the package substrate 4 are indicated by dashed lines.

The optical communication device 101 of the first embodiment is designed as an optical receiver. The optical communication device 101 is formed by connecting a plurality of pad electrodes formed on the semiconductor chip 2 that is the first chip, to a plurality of pad electrodes formed on the semiconductor chip 3 that is the second chip. The semiconductor chips 2 and 3 of the first embodiment are connected by forming metal between the pads of the two chips on one surface of the package substrate 4 by a flip-chip method.

The semiconductor chip 2 includes an optical waveguide 8 formed inside the chip, and a plurality of first electrode pads for outputting an electrical signal indicating the intensity of light propagating in the optical waveguide 8. As illustrated in FIGS. 1(a) and 2(a), the first electrode pads of the first embodiment include ground pads (hereinafter referred to as “G pads”) 22 and 26, signal pads (hereinafter referred to as “S pads”) 23 and 25, and a power supply pad (hereinafter referred to as “P pad”) 24 that supplies drive power to a dual photodiode 21. Further, the semiconductor chip 2 includes the dual photodiode 21 that includes photodiodes 21a and 21b. The dual photodiode 21 has a function of converting light input via the optical waveguide 8 into an electrical signal. The G pads 22 and 26, the S pads 23 and 25, and the P pad 24 mentioned above function in cooperation with each other to output electrical signals.

As illustrated in FIG. 2(b), the package substrate 4, which is a board, includes electrical signal lines 41, 42, 43, 44, and 45 connected to the G pads 22 and 26, the S pads 23 and 25, and the P pad 24. The lines 41 to 45 are formed on a surface of or inside the package substrate 4. As illustrated in FIG. 2(b), of the lines, the lines 41 and 45 connected to the G pads 22 and 26 are disposed inside the package substrate 4, and other lines 42 and 44 are provided on the upper surface of the package substrate 4. A part of the line 43 connected to the P pad 24 is provided on the upper surface of the package substrate 4, and the other part is provided inside the package substrate 4. Further, as illustrated in FIG. 2(b), G pads 12a, 12b, 16a, and 16b, S pads 13a, 13b, 15a, and 15b, and P pads 14a and 14b, which are pads on the side of the package substrate 4, are provided on the upper surface of the package substrate 4.

The lines 42, 43, and 44, and the G pads 12a, 12b, 16a, and 16b, the S pads 13a, 13b, 15a, and 15b, and the P pads 14a and 14b illustrated in FIG. 2(b) are formed on the upper surface of the package substrate 4. The G pads 12a, 12b, 16a, and 16b are in contact with metal or the like exposed through the upper surface of the package substrate 4.

As illustrated in FIGS. 1(a) and 2(a), the semiconductor chip 3, which is the second chip, includes G pads 32 and 36, and S pads 33 and 35 that are a plurality of second electrode pads electrically connected to the G pads 22 and 26, and the S pads 23 and 25 of the semiconductor chip 2. Further, as illustrated in FIGS. 1(a) and 2(a), the semiconductor chip 3 includes a core circuit 7 on the lower surface. The core circuit 7 is a circuit including an element that processes a signal generated by the dual photodiode 21, and may be any circuit that matches the functions and the specification of the optical communication device 101. An example of the core circuit 7 may be a circuit including a transimpedance amplifier that amplifies a signal, for example.

As illustrated in FIG. 1(a), the semiconductor chip 3, together with the semiconductor chip 2, is connected to the line 41 and the like of the package substrate 4 via the G pad 32 and the like. At this point of time, the semiconductor chips 2 and 3 are connected to the package substrate 4 so that the lower surfaces of the region A2 and the region A3 shown in FIG. 2(a) overlap the upper surface of the region A4 shown in FIG. 2(b). As a result, an electrical path is formed with the G pads 22 and 12a, the line 41, and the G pads 12b and 32. Likewise, a path is formed with the S pads 23 and 13a, the line 42, and S pads 13b and 33, a path is formed with the P pads 24 and 14a, the line 43, and the P pad 14b, a path is formed with the S pads 25 and 15a, the line 44, and the S pads 15b and 35, and a path is formed with the G pads 26 and 16a, the line 45, and the G pads 16b and 36.

The optical communication device 101 has the above configuration as one unit (channel), and includes a plurality of channels.

With the above configuration, as illustrated in FIG. 1(a), the center points of the signal pads 23 and 25 among the electrode pads of the semiconductor chip 2 are located on a straight line L₂ parallel to the side E₁ of the semiconductor chip 2 facing the semiconductor chip 3 in the first embodiment. The center points of the G pads 22 and 26 and the P pad 24, which are the other first electrode pads, are located on a straight line L₁ located farther from the side E₁ than the straight line L₂.

A straight line parallel to the side E₁ in the present embodiment is only required to be parallel when visually observed. In many cases, two semiconductor chips connected to one package substrate have a shape in which sides facing each other are parallel to each other in order to shorten signal lines or reduce the size of the device. In the first embodiment, straight lines L₁ to L₄ are straight lines parallel to the side E₁ facing the other chip and a side E₂ of the semiconductor chip 3. Further, the straight lines L₁ to L₄ are straight lines located on at least one of the semiconductor chips 2 and 3.

Furthermore, in the first embodiment, the center points of the signal pads 33 and 35 of the electrode pads of the semiconductor chip 3 are also located on the straight line L₃ parallel to the side E₁. The center points of the G pads 32 and 36, which are the other second electrode pads, are located on the straight line L₄ located farther from the side E₁ than the straight line L₃. That is, in the first embodiment, in both the semiconductor chip 2 and the semiconductor chip 3, the S pads are disposed closer to the side E₁ than the other electrode pads. However, the first embodiment is not limited to such a configuration, and the S pads may be disposed closer to the side E₁ than the other electrode pads in either the semiconductor chip 2 or the semiconductor chip 3. In the first embodiment, the center points of all the S pads of the semiconductor chips 2 and 3 are also located on a straight line closer to the side E₁ than the other G pads and the like. However, in the first embodiment, the center points of only some of the S pads may be located on a straight line closer to the side E₁ than the G pads and the like.

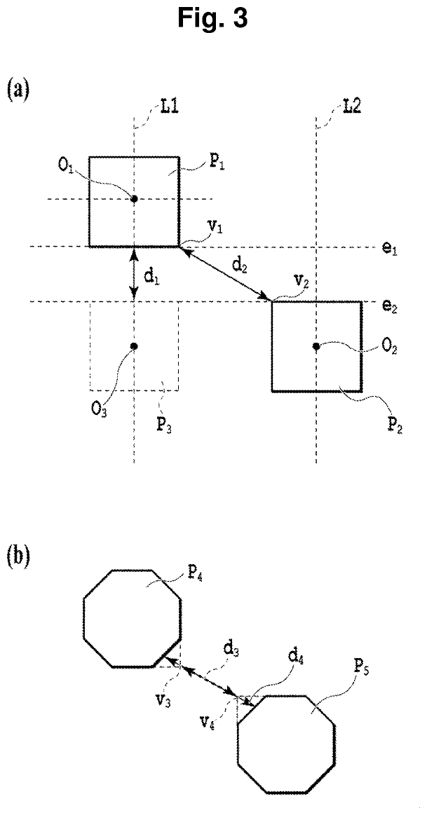

FIG. 3(a) is a diagram for explaining the effects of the above configuration, and illustrates pads P₁ and P₂, and a pad P₃. The pad P₁ is disposed so that its center point O₁ is located on the straight line L₁. The pad P₃ is a virtual electrode pad that is located so that its center point O₃ is located on the straight line L₁, like the pad P₁. The pad P₂ is an electrode pad disposed so that its center point O₂ is located on the straight line L₂ different from the straight line L₁. Dotted lines e₁ and e₂ are lines collinear with the facing sides of the pads P₁ and P₂, and the distance d₁ between the dotted lines e₁ and e₂ indicates the shortest distance between the pads P₁ and P₃. In the description below, the effects in a case where the virtual pad P₃ is moved so as to slide in a direction orthogonal to the straight lines L₁ and L₂, and is then disposed therein is explained.

As illustrated in FIG. 3(a), the shortest distance d₂ between the vertexes v₁ and v₂ at which the pad P₁ and the pad P₂ are closest to each other is the interval between the intersections of the dotted lines e₁ and e₂ with a straight line obliquely intersecting the dotted lines e₁ and e₂. Therefore, it is apparent that the shortest distance d₂ is longer than the shortest distance d₁ equal to the interval between the intersections of the dotted lines e₁ and e₂ with a straight line perpendicular to the dotted lines e₁ and e₂. Further, the first embodiment is not limited to such a layout, and the center points of the electrode pads can be disposed on two or more different straight lines parallel to the side E₁, to alleviate the restriction on the lengths of the channels in the direction of arrangement, and widen the interval between electrode pads whose center points are located on one straight line. According to the first embodiment described above, the intervals between electrode pads are widened without any change in the number and the size of the electrode pads disposed on the semiconductor chips 2 and 3, and the parasitic capacitance to be applied to the electrode pads is reduced, to prevent degradation of the quality of high-speed signals. Thus, an optical communication device advantageous for miniaturization can be obtained.

In addition to the above configuration, the shape of each electrode pad in a top view is an octagon that is a polygon having a larger even number of vertexes than a quadrangle in the first embodiment, as illustrated in FIGS. 1(a), 2(a), and 2(b). With such a configuration, the shortest distance between the electrode pads can be made even longer in the first embodiment. However, in the first embodiment, the shape of each electrode pad is not limited to an octagon, but the shape of each electrode pad may be a polygon having a larger number of vertexes.

FIG. 3(b) is a diagram for explaining the above configuration, and illustrates the upper surfaces of an octagonal electrode pad P₄ and an electrode pad P₅ whose center point is located on a straight line different from the electrode pad P₄. Vertexes v₃ and v₄ in FIG. 3(b) are virtual vertexes in a case where the pads P₄ and P₅ are both quadrangular. In a case where the electrode pads P₄ and P₅ each have a quadrangular shape in a top view, the shortest distance between the electrode pads P₄ and P₅ is the distance d₃ between the facing vertexes v₃ and v₄. However, when the shape of the electrode pads P₄ and P₅ viewed from above is an octagonal shape, the shortest distance between the electrode pads P₄ and P₅ is the distance d₄ between straight lines closer to the center points of the electrode pads P₄ and P₅ than the vertexes v₃ and v₄. That is, with the electrode pads whose center points are located on different straight lines and whose shape in a top view is an octagonal shape, it is possible to increase the interval between the electrode pads, without any change in the number of the electrode pads disposed on the semiconductor chips 2 and 3, and without any reduction in the substantial area connected to the terminals among the electrode pads. Accordingly, in the first embodiment, the parasitic capacitance to be applied to the electrode pads can be reduced, and degradation of the quality of high-speed signals can be prevented. Thus, an optical communication device advantageous for miniaturization can be obtained.

In particular, in the next generation of 64 Gbaud and 16 QAM systems that realize 400 Gbps, ultrafast modulation techniques such as 100 Gbaud and 128 Gbaud have been studied. With such high transmission rates, disturbance of impedance is more likely to adversely affect signal quality. For this reason, the signal-ground distance becomes shorter, and parasitic capacitance is likely to be applied, particularly in the vicinities of pads having a larger size than that of a signal line. The first embodiment described above is applied to such an ultrafast modulation technique, and can reduce the influence of parasitic capacitance.

Furthermore, as illustrated in FIG. 1, in the first embodiment, the S pads 23 and 33, and the S pads 25 and 35 that exchange electrical signals are disposed at positions closer to the sides E₁ and E₂ than the G pads 22, 32, 26, and 36, and the P pad 24. With such a configuration, signal lines can be shortened, and communication speed can be increased. In general, the G pad 22 and the like, or the P pad 24 is preferably disposed at a distance of 50 μm or longer from the side E₁ in the first embodiment.

### Second Embodiment

Next, a second embodiment of the present disclosure is described. An optical communication device 201 of the second embodiment aims to ensure ease of on-wafer high-frequency measurement, in addition to the effect of reducing parasitic capacitance as in the first embodiment.

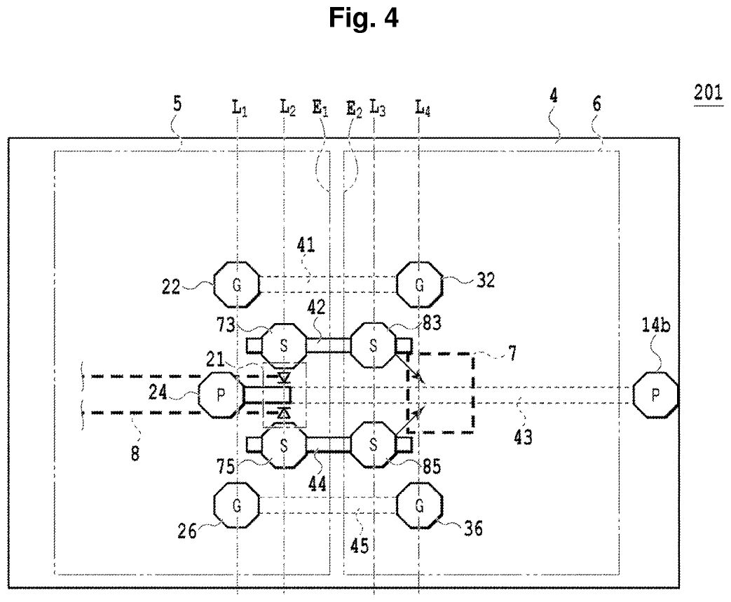

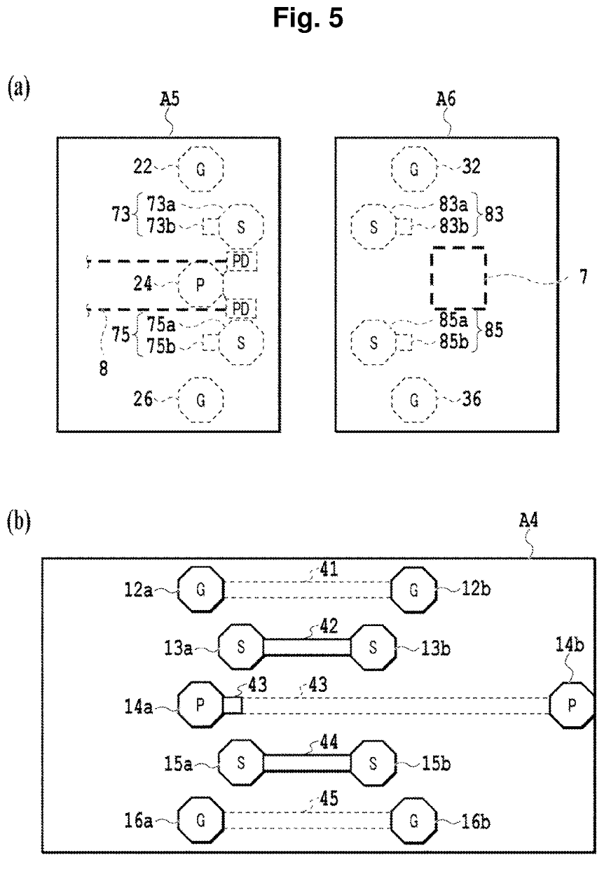

FIGS. 4, 5(a), and 5(b) are diagrams for explaining the optical communication device of the second embodiment. FIG. 4 is a top view of the optical communication device 201 of the second embodiment. FIG. 5(a) is a view of a partial region A5 of a semiconductor chip 5 and a partial region A6 of a semiconductor chip 6 of the second embodiment as viewed from above. FIG. 5(b) is a view of a partial region A4 of a package substrate 4 of the second embodiment as viewed from above. The semiconductor chip 5 differs from the semiconductor chip 2 only in the shape of the S pads, and the semiconductor chip 6 differs from the semiconductor chip 3 only in the shape of the S pads. As illustrated in FIGS. 4, 5(a), and 5(b), in the second embodiment, S pads 73a and 75a among the electrode pads of the semiconductor chip 5 include measurement protrusions 73b and 75b. In the second embodiment, the measurement protrusion 73b and the S pad 73a are collectively referred to as a protruding S pad 73. Likewise, the S pads having measurement protrusions are referred to as protruding S pads 75, 83, and 85.

Also, in the semiconductor chip 6 of the second embodiment, a protruding S pad 83 that is one of the electrode pads includes an S pad 83a and a measurement protrusion 83b, and a protruding S pad 85 includes an S pad 85a and a measurement protrusion 85b. However, in the second embodiment, electrode pads having a measurement protrusion are not necessarily provided on both of the semiconductor chips 5 and 6 as described above, but either one of the semiconductor chips may have electrode pads each having a measurement protrusion. Also, in the second embodiment, electrode pads each having a measurement protrusion are not necessarily used the S pads as in the semiconductor chips 5 and 6, but electrode pads each having a measurement protrusion may be used for all the electrode pads or only for the electrode pads related to power supply. The use of electrode pads each having a measurement protrusion can be determined as appropriate, in accordance with the specification for on-wafer inspection of semiconductor chips.

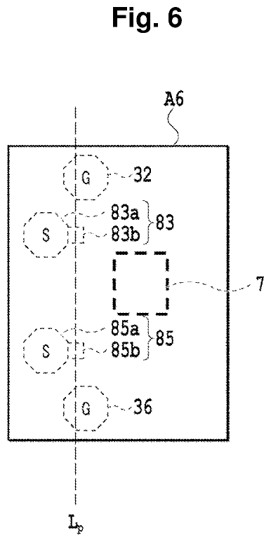

FIG. 6 is a diagram for explaining a state of on-wafer measurement, taking the semiconductor chip 6 as an example. A straight line L_{P} shown in FIG. 6 is a straight line connecting tips (points) of a plurality of probe needles in contact with the electrode pads of the semiconductor chip 6. In the second embodiment, the straight line L_{P} coincides with a straight line parallel to the sides E₁ and E₂. As illustrated in FIG. 4, the G pads 32 and 36, and the S pads 83a and 85a are disposed such that centers thereof are located on the different straight lines L₃ and L₄, respectively. A measuring device brings the probe needles into contact with equally spaced points on the straight line L_{P}. At this point of time, the measurement protrusions 83b and 85b of the protruding S pads 83 and 85 extend onto the straight line L_{P} passing through the G pads 32 and 36, and therefore, the G pads 32 and 36 and the measurement protrusions 83b and 85b overlap the straight line L_{P}. Accordingly, in the second embodiment, the plurality of probe needles whose tips are located on a straight line are lowered onto the semiconductor chip 6, and electrical signals can be obtained from all of the G pads 32 and 36, and the protruding S pads 83 and 85. Thus, in the second embodiment, it is possible to use superhigh frequency probes that are arranged on a straight line and are easy to design and manufacture with a constant impedance, while reducing parasitic capacitance by preventing the center points of all the electrode pads from being located on one straight line.

The above configuration can also be formed in the semiconductor chip 5. That is, as illustrated in FIG. 4, in the semiconductor chip 5, the G pads 22 and 26, the P pad 24, and the protruding S pads 73 and 75 are located on the different straight lines L₁ and L₂, and the measurement protrusions 73b and 75b protrude from the S pads 73a and 75a toward the straight line L₁. Accordingly, the probes that bring probe needles down onto one straight line can bring the probe needles into contact with the G pads 22 and 26, the P pad 24, and the measurement protrusions 73b and 75b all at once.

### Third Embodiment

Next, a third embodiment is described. An optical transmitter of the third embodiment is formed by connecting both semiconductor chips 2 and 3 to a package substrate 4, as in the first embodiment. However, the third embodiment aims to match delay times of signal lines in a case where the lengths of signal paths differ between the S pads 23 and 25 of the semiconductor chip 2, or the lengths of signal paths differ between the S pads 33 and 35 of the semiconductor chip 3. For this purpose, in the third embodiment, the semiconductor chip 2 has two photodiodes 21a and 21b that convert light propagating in an optical waveguide 8 into electrical signals, and the semiconductor chip 3 includes a core circuit 7 that is a supply receiving circuit that receives supply of electrical signals. Further, the length of the signal path from one of the photodiodes (the photodiode 21a, for example) to the core circuit 7 via a line 42 is made equal to the length of the signal path from the other one of the photodiodes (the photodiode 21b, for example) to the core circuit 7 via another line 44.

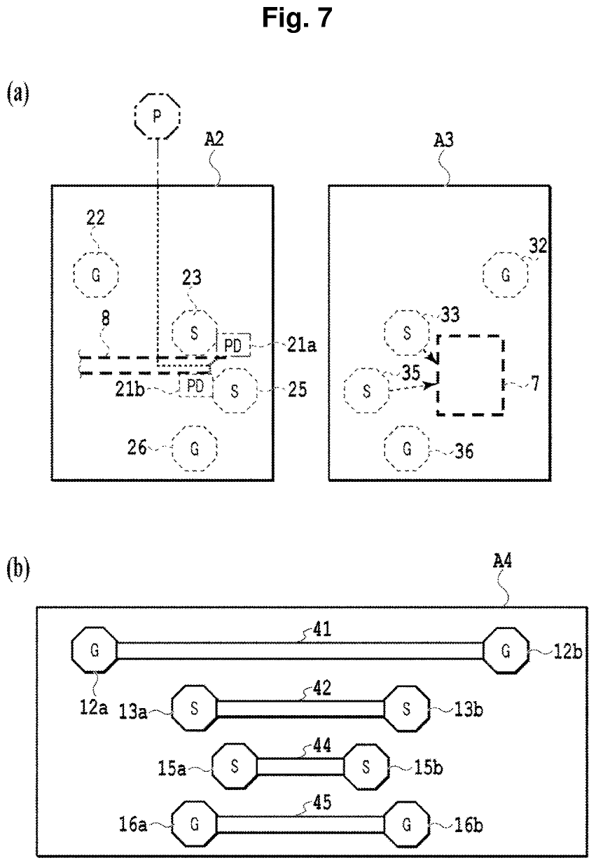

FIGS. 7(a), and 7(b) are diagrams for explaining the optical communication device of the third embodiment. FIG. 7(a) is a view of a partial region A2 of the semiconductor chip 2 and a partial region A3 of the semiconductor chip 3 of the third embodiment as viewed from above. FIG. 7(b) is a view of a partial region A4 of the package substrate 4 as viewed from above. In the third embodiment, the P pad is provided outside the region A2. Further, the S pads 23 and 25 are not located on one straight line, and the S pad 23 is disposed close to the photodiode 21a and farther from the semiconductor chip 3 than the S pad 25. In the semiconductor chip 3, on the other hand, the S pad 33 is disposed at a position closer to the core circuit 7 than the S pad 35. In such a case, in the third embodiment, the length of the signal path from the photodiode 21a to the core circuit 7, and the length of the signal path from the photodiode 21b to the core circuit 7 are made equal to each other. That is, in the example illustrated in FIGS. 7(a) and 7(b), the length of the signal path between the S pads 23 and 33 and between the S pad 33 and the core circuit 7 is made equal to the length of the signal path between the S pads 25 and 35 and between the S pad 35 and the core circuit 7, and the equal length design is performed so that delay times of both signals become equal to each other.

In the example illustrated in FIG. 7(b), the lengths of the lines 42 and 44, which are part of the signal paths, are changed on the basis of the positions of the S pads 23, 25, 33, and 35 in the semiconductor chips 2 and 3, so that equal length design is performed. In the example illustrated in FIG. 7(b), both the lines 42 and 44 each have a linear shape. However, in the third embodiment, in a case where it is necessary to extend the lines, the lines may be bent, for example. Further, in a case where the lines are bent, reflection and induction caused in electrical signals at the bent portions may be taken into consideration in the third embodiment. In this manner, the timings at which two electrical signals generated in the photodiodes 21a and 21b are input to the core circuit 7 can be matched to each other, and the operating accuracy of the optical communication device can be enhanced.

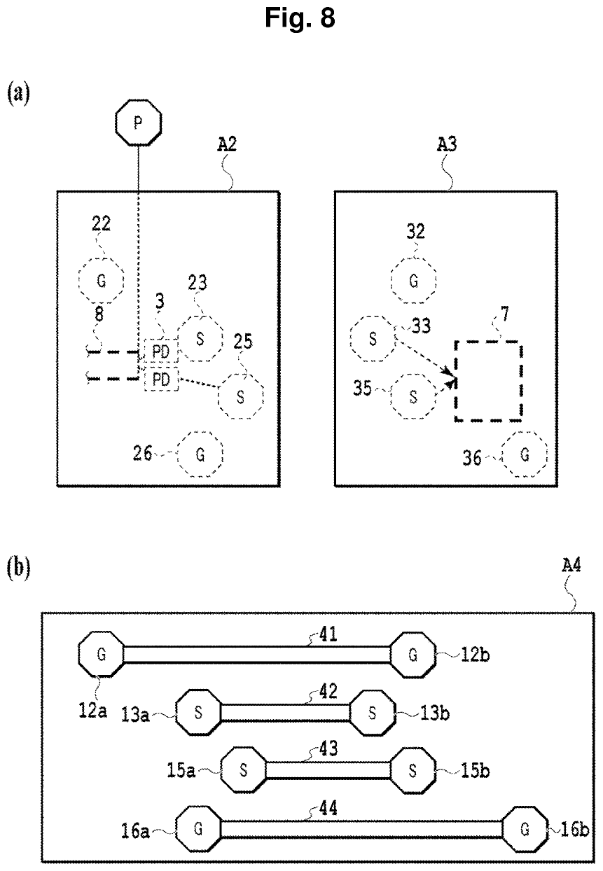

FIGS. 8(a), and 8(b) are diagrams for explaining another example of the optical communication device of the third embodiment. FIG. 8(a) is a view of a partial region A2 of the semiconductor chip 2 and a partial region A3 of the semiconductor chip 3 of the third embodiment as viewed from above. FIG. 8(b) is a view of a partial region A4 of the package substrate 4 as viewed from above. In the example illustrated in FIGS. 8(a) and 8(b), all the lengths of the lines 41, 42, 43, and 44 formed on the package substrate 4 are made equal, the positions of the S pads 23, 25, 33, and 35 on the semiconductor chips 2 and 3 are adjusted to make the lengths of the two signal lines equal, and delay times of both signals are made equal.

That is, in the third embodiment illustrated in FIGS. 8(a) and 8(b), the lengths of the lines 42 and 43 are made equal to each other, so that delay times of signals in the lines 42 and 43 become equal to each other. Therefore, in the third embodiment, the S pad 23 is disposed closer to the photodiodes than the S pad 25 in the semiconductor chip 2. Further, in the third embodiment, the S pad 33 is disposed farther from the core circuit 7 than the S pad 35 in the semiconductor chip 3. An electrical signal generated by the photodiode 21a is input from the S pad 23 to the core circuit 7 via the S pad 33. Also, an electrical signal generated by the photodiode 21b is input from the S pad 25 to the core circuit 7 via the S pad 35. Accordingly, with the above configuration, equal length design can be performed so that the length of the signal path from the photodiode 21a to the core circuit 7 becomes equal to the length of the signal path from the photodiode 21b to the core circuit 7.

In particular, the electrical reflection characteristics of a photodiode and a transimpedance amplifier, or an optical modulator and a modulator driver of an open collector type are not low-reflection characteristics but total reflection characteristics. For this reason, wiring lines connected to these elements are likely to affect frequency characteristics due to multiple reflection of electrical high-frequency waves, and it is necessary to appropriately design impedances and lengths. The third embodiment described above can also be applied to fields in which such high-precision design is required.

### Fourth Embodiment

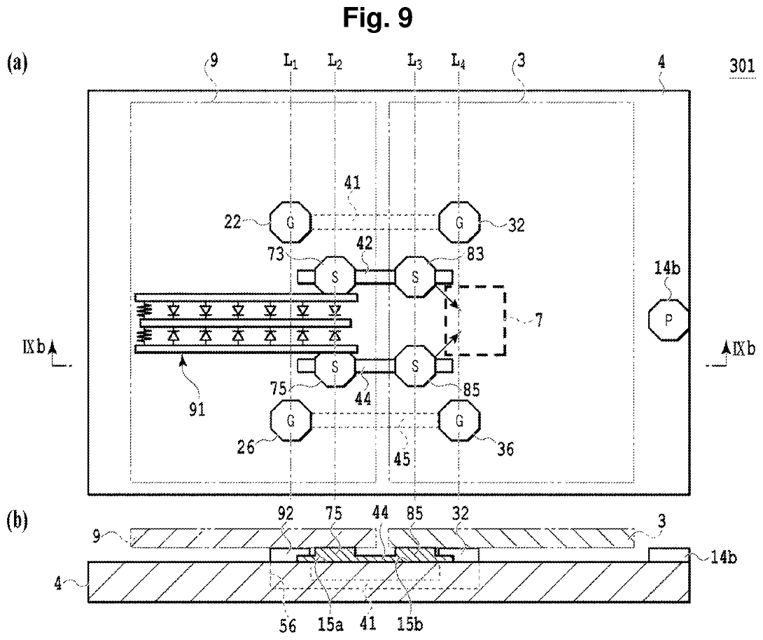

Next, a fourth embodiment is described. FIG. 9(a) is a top view of an optical communication device 301 of the fourth embodiment. FIG. 9(b) is a cross-sectional view taken along the line between arrows IXb and IXb. While each of the optical communication devices of the first to third embodiments functions as a receiver, the optical communication device 301 of the fourth embodiment has a plurality of channels including a chip of a Mach-Zehnder optical modulator 91 and a modulator driver, and functions as a transmitter. In the fourth embodiment, a core circuit 7 functions as a modulator driver. The optical communication device 301 is formed by connecting a semiconductor chip 9 including the Mach-Zehnder optical modulator 91 and a semiconductor chip 3 to a package substrate 4.

In the example of the optical communication device 301 illustrated in FIG. 9(a), protruding S pads 73, 75, 83, and 85 each having a measurement protrusion are used, as in the second embodiment. G pads 22 and 26 are disposed so that the center points are located on a straight line L₁. Also, G pads 32 and 36 are disposed so that the center points are located on a straight line L₄.

### Fifth Embodiment

Next, a fifth embodiment is described. While electrode pads are connected with lines in each of the first to fourth embodiments, a semiconductor chip 2 and a semiconductor chip 3 overlap, and are connected directly to each other in the fifth embodiment.

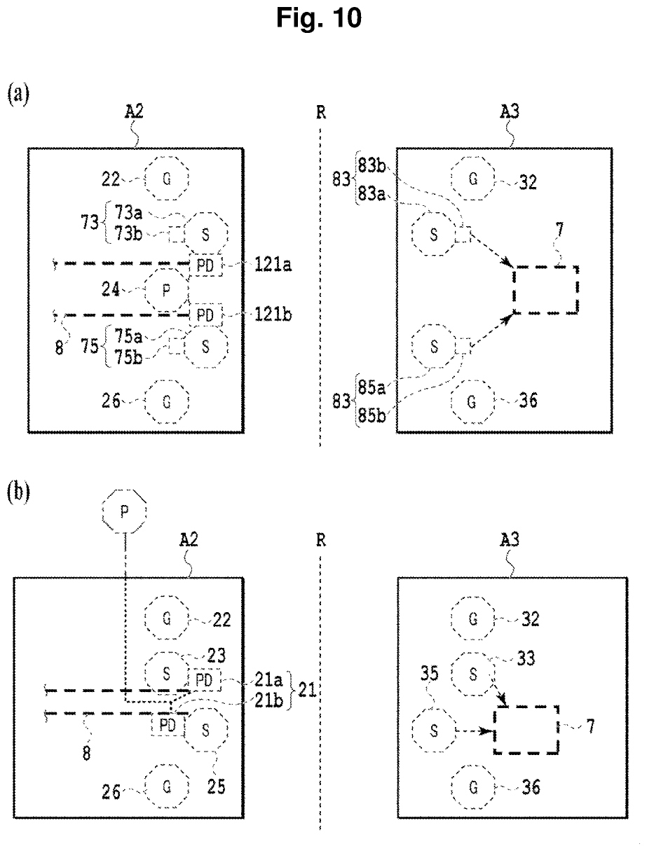

FIGS. 10(a) and 10(b) are diagrams for explaining the fifth embodiment. FIGS. 10(a) and 10(b) each illustrate upper surfaces in a state before a region 2A of the semiconductor chip 2 and a region 3A of the semiconductor chip 3 overlap each other. FIG. 10(a) illustrates an example in which the semiconductor chips 2 and 3 are designed in the same manner as those in the first embodiment. FIG. 10(b) illustrates an example in which the lengths of signal paths of S pads 23 and 25 are different in the semiconductor chip 2, and the lengths of signal paths of S pads 33 and 35 are different in the semiconductor chip 3, as in the third embodiment. In the fifth embodiment, one of the semiconductor chips 2 and 3 in one of the states illustrated in FIGS. 10(a) and 10(b) is disposed so as to be reversed about a rotation axis R parallel to a straight line such as the straight line L₁ shown in FIG. 1 or the like, and is connected to the other chip in an overlapping manner. At this point of time, in the fifth embodiment illustrated in FIG. 10(a), G pads 22 and 32 are connected directly to each other (without any line), protruding S pads 73 and 83 are connected directly to each other, P pads 24 and 14b are connected via a line 34, protruding S pads 75 and 85 are connected directly to each other, and G pads 26 and 36 are connected directly to each other. Meanwhile, in the fifth embodiment illustrated in FIG. 10(b), the G pads 22 and 32 are connected directly to each other, the S pads 23 and 33 are connected directly to each other, the S pads 25 and 35 are connected directly to each other, and the G pads 26 and 36 are connected directly to each other.

As illustrated in FIGS. 10(a) and 10(b), the above configurations can be obtained by disposing the G pads, the S pads, and the P pads in a line-symmetric layout with respect to the rotation axis R in the semiconductor chips 2 and 3. Note that such a layout of the electrode pads is possible between the surfaces of the semiconductor chips 2 and 3 on which the electrode pads are formed, or between the back surfaces on the opposite sides from these surfaces, as illustrated in FIGS. 10(a) and 10(b). Note that, of the fifth embodiment, the example illustrated in FIG. 10(b) requires equal length design for wiring lines, like the third embodiment.

Note that the fifth embodiment does not specify that one of the semiconductor chips 2 and 3 is rotated about the rotation axis R, the front and back of the one semiconductor chip are reversed, and the one semiconductor chip is connected to the other in the step of connecting the semiconductor chips 2 and 3, but specifies that the semiconductor chips 2 and 3 are disposed in this manner as a result of a configuration in which the semiconductor chips 2 and 3 are connected directly to each other.

In the first to fifth embodiments described above, example cases where the number of channels is four on the assumption of a digital coherent optical receiver have been explained. However, the present disclosure is only required to provide a differential optical receiver even if the number of channels is small, and can also be applied to optical receiving schemes such as differential phase shift keying (DPSK) and differential quadrature phase shift keying (DQPSK), for example.

### REFERENCE SIGNS LIST

2, 3, 5, 6, 9 semiconductor chip
4 package substrate
7 core circuit
8 optical waveguide
21 dual photodiode
21a, 21b photodiode
12a, 12b, 16a, 16b, 22, 26, 32, 36 G pad
13a, 13b, 15a, 15b, 23, 25, 33, 35, 73a, 75a, 83a, 85a S pad
14a, 14b, 24, 34 P pad
41, 42, 43, 44, 45 line
56 via
73, 75, 83, 85 protruding S pad
73b, 75b, 83b, 85b measurement protrusion
91 Mach-Zehnder optical modulator
101, 201, 301 optical communication device

1. An optical communication device comprising:
a first chip including an optical waveguide, and a plurality of first electrode pads for outputting an electrical signal indicating intensity of light propagating in the optical waveguide;
a second chip including a plurality of second electrode pads that are connected directly to the first electrode pads, or are electrically connected to the first electrode pads via another substrate,
wherein
the first electrode pads and the second electrode pads include a plurality of signal pads that transmit the electrical signal, and
center points of at least some signal pads of the plurality of signal pads are located on a straight line on at least one of the first chip and the second chip, the straight line being a line parallel to a side facing the other one of the first chip and the second chip, and center points of the other first electrode pads and the other second electrode pads are located on another straight line farther from the facing side than the straight line.

2. The optical communication device according to claim 1, wherein at least some first electrode pads of the first electrode pads each have a measurement protrusion joined to each corresponding first electrode pad, and the measurement protrusions are located on the straight line.

3. The optical communication device according to claim 1, wherein at least some second electrode pads of the second electrode pads each have a measurement protrusion joined to each corresponding second electrode pad, and the measurement protrusions are located on the straight line.

4. The optical communication device according to claim 1, wherein at least some electrode pads of the first electrode pads or the second electrode pads each have a polygonal shape having a larger even number of vertexes than a quadrangle in a top view.

5. The optical communication device according to claim 1, where
the first chip includes at least two photodiodes that convert light propagating in the optical waveguide into the electrical signal, and the second chip includes a supply receiving circuit that receives supply of the electrical signal, and
a delay time of a signal path from one of the photodiodes to the supply receiving circuit is equal to a delay time of a signal path from another one of the photodiodes to the supply receiving circuit.

6. The optical communication device according to claim 1,
which has a plurality of channels including a photodiode and a transimpedance amplifier and functions as an optical receiver, or has a plurality of channels including a modulator driver and a Mach-Zehnder optical modulator and functions as an optical transmitter.

7. The optical communication device according to claim 1, wherein one of the first chip and the second chip is rotated about the straight line and is reversed, and is overlapped with the other one of the first chip and the second chip.
